(19) United States
(12) Patent Application Publication
(10) Pub. No.: US 2025/0274038 A1
(43) Pub. Date: Aug. 28, 2025

(54) ELECTROMAGNATIC INTERFERENCE FILTER FOR ELECTRIC VEHICLE TRACTION INVERTER

(71) Applicant: FORD GLOBAL TECHNOLOGIES, LLC, Dearborn, MI (US)

(72) Inventors: Petros G. TASKAS, Novi, MI (US); Baoming GE, Okemos, MI (US)

(21) Appl. No.: 18/585,774

(22) Filed: Feb. 23, 2024

(51) Int. Cl. H02M 1/44; B60R 16/02

(52) U.S. Cl. CPC H02M 1/44; B60R 16/02

(57) ABSTRACT

An inverter system controller for an automotive vehicle includes a housing and has disposed within the housing a Y-capacitor defining a terminal, a ground busbar, and a surface mount resistor in direct contact with the terminal and ground busbar to form an electromagnetic filter that lacks a printed circuit board.

### TECHNICAL FIELD

The present disclosure relates to an inverter for an electric vehicle (EV). More specifically the present disclosure relates to an electromagnetic interference (EMI) filter for an EV inverter.

### BACKGROUND

Electric vehicles rely on one or more power inverters to convert electric energy between direct-current (DC) and alternating-current (AC) forms for supplying power to an electric machine for propulsion. During the operation, the inverter may emit EMI.

### SUMMARY

A vehicle comprises an electric machine for propelling the vehicle, a battery for supplying electric power to the electric machine, and an electromagnetic interference filter. The electromagnetic interference filter is connected between the electric machine and battery, and includes a housing, a capacitor disposed within and insulated from the housing, a ground busbar attached to the housing, a resistor having a first terminal connected to a terminal of the capacitor and a second terminal connected to the ground busbar, and an insulating cover at least partially covering a top surface of the capacitor.

An automotive system comprises automotive power electronics including an electromagnetic interference filter, that lacks a printed circuit board, disposed within a housing of an inverter system controller.

An automotive component comprises an inverter system controller including a housing and having disposed within the housing a Y-capacitor defining a terminal, a ground busbar, and a surface mount resistor in direct contact with the terminal and ground busbar to form an electromagnetic filter that lacks a printed circuit board.

### BRIEF DESCRIPTION OF THE DRAWINGS

FIG. 1 is a diagram of an electrified vehicle illustrating drivetrain and energy storage components including an electric machine.

FIG. 2 is a circuit diagram of a power inverter and an EMI filter for an electric machine.

FIG. 3 is a design diagram of an EMI filter.

FIG. 4A is a design diagram showing an enlarged portion of an insulating cover.

FIG. 4B is another design diagram showing an enlarged portion of an insulating cover.

FIG. 5 is a design diagram of the EMI filter showing an enlarged portion of another embodiment.

### DETAILED DESCRIPTION

Embodiments are described herein. It is to be understood, however, that the disclosed embodiments are merely examples and other embodiments may take various and alternative forms. The figures are not necessarily to scale. Some features could be exaggerated or minimized to show details of particular components. Therefore, specific structural and functional details disclosed herein are not to be interpreted as limiting, but merely as a representative basis for teaching one skilled in the art.

Various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

The present disclosure, among other things, proposes an EMI filter design for an EV power inverter.

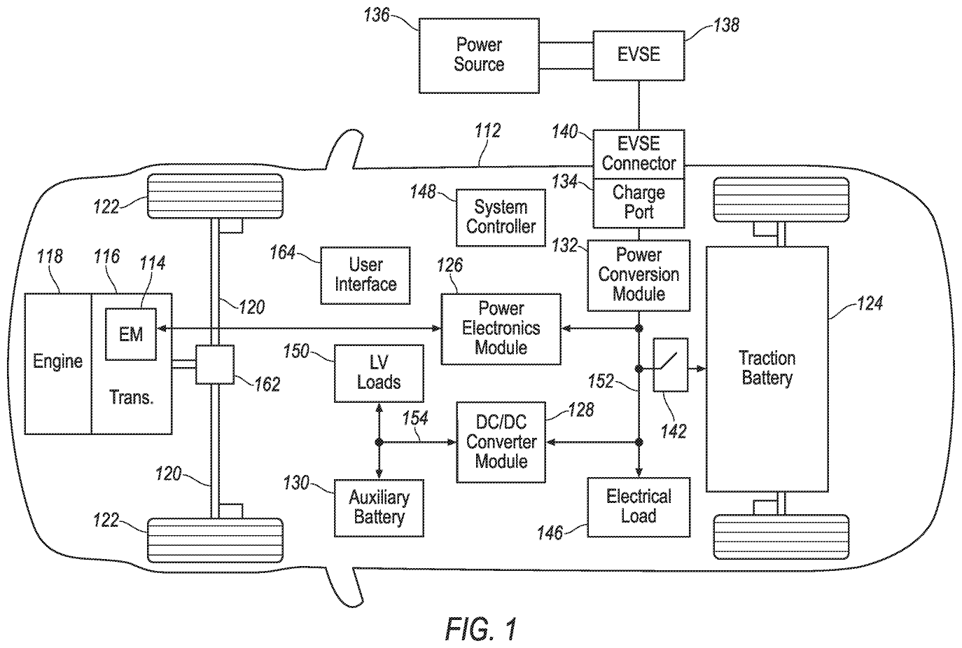

FIG. 1 depicts an electrified vehicle 112 that may be referred to as a plug-in hybrid-electric vehicle (PHEV). A plug-in hybrid-electric vehicle 112 may comprise one or more electric machines 114 mechanically coupled to a hybrid transmission 116. The electric machines 114 may be capable of operating as a motor or a generator. In addition, the hybrid transmission 116 is mechanically coupled to an engine 118. The hybrid transmission 116 is also mechanically coupled to a drive shaft 120 that is mechanically coupled to the wheels 122. The electric machines 114 can provide propulsion and braking capability when the engine 118 is turned on or off. The electric machines 114 may also function as generators and can provide fuel economy benefits by recovering energy that would normally be lost as heat in a friction braking system. The electric machines 114 may also reduce vehicle emissions by allowing the engine 118 to operate at more efficient speeds and allowing the hybrid-electric vehicle 112 to be operated in electric mode with the engine 118 off under certain conditions. An electrified vehicle 112 may also be a battery electric vehicle (BEV). In a BEV configuration, the engine 118 may not be present.

A traction battery or battery pack 124 stores energy that can be used by the electric machines 114. The vehicle battery pack 124 may provide a high voltage direct current (DC) output. The traction battery 124 may be electrically coupled to one or more power electronics modules 126 (also referred to as a traction inverter). One or more contactors 142 may isolate the traction battery 124 from other components when opened and connect the traction battery 124 to other components when closed. The power electronics module 126 is also electrically coupled to the electric machines 114 and provides the ability to bi-directionally transfer energy between the traction battery 124 and the electric machines 114. For example, a traction battery 124 may provide a DC voltage while the electric machines 114 may operate with a three-phase alternating current (AC) to function. The power electronics module 126 may convert the DC voltage to a three-phase AC current to operate the electric machines 114. In a regenerative mode, the power electronics module 126 may convert the three-phase AC current from the electric machines 114 acting as generators to the DC voltage compatible with the traction battery 124.

The vehicle 112 may include a variable-voltage converter (VVC) (not shown) electrically coupled between the traction battery 124 and the power electronics module 126. The VVC may be a DC/DC boost converter configured to increase or boost the voltage provided by the traction battery 124. By increasing the voltage, current requirements may be decreased leading to a reduction in wiring size for the power electronics module 126 and the electric machines 114. Further, the electric machines 114 may be operated with better efficiency and lower losses.

In addition to providing energy for propulsion, the traction battery 124 may provide energy for other vehicle electrical systems. The vehicle 112 may include a DC/DC converter module 128 that converts the high voltage DC output of the traction battery 124 to a low voltage DC supply that is compatible with low-voltage vehicle loads. An output of the DC/DC converter module 128 may be electrically coupled to an auxiliary battery 130 (e.g., 12V battery) for charging the auxiliary battery 130. The low-voltage systems may be electrically coupled to the auxiliary battery 130. One or more electrical loads 146 may be coupled to the high-voltage busbar/rail. The electrical loads 146 may have an associated controller that operates and controls the electrical loads 146 when appropriate. Examples of the electrical loads 146 may be a fan, an electric heating element and/or an air-conditioning compressor.

The electrified vehicle 112 may be configured to recharge the traction battery 124 from an external power source 136. The external power source 136 may be a connection to an electrical outlet. The external power source 136 may be electrically coupled to a charger or electric vehicle supply equipment (EVSE) 138. The external power source 136 may be an electrical power distribution network or grid as provided by an electric utility company. The EVSE 138 may provide circuitry and controls to manage the transfer of energy between the power source 136 and the vehicle 112. The external power source 136 may provide DC or AC electric power to the EVSE 138. The EVSE 138 may have a charge connector 140 for plugging into a charge port 134 of the vehicle 112. The charge port 134 may be any type of port configured to transfer power from the EVSE 138 to the vehicle 112. The charge port 134 may be electrically coupled to a charger or on-board power conversion module 132. The power conversion module 132 may condition the power supplied from the EVSE 138 to provide the proper voltage and current levels to the traction battery 124. The power conversion module 132 may interface with the EVSE 138 to coordinate the delivery of power to the vehicle 112. The EVSE connector 140 may have pins that mate with corresponding recesses of the charge port 134. Alternatively, various components described as being electrically coupled or connected may transfer power using a wireless inductive coupling.

Electronic modules in the vehicle 112 may communicate via one or more vehicle networks. The vehicle network may include a plurality of channels for communication. One channel of the vehicle network may be a serial bus such as a Controller Area Network (CAN). One of the channels of the vehicle network may include an Ethernet network defined by the Institute of Electrical and Electronics Engineers (IEEE) 802 family of standards. Additional channels of the vehicle network may include discrete connections between modules and may include power signals from the auxiliary battery 130. Different signals may be transferred over different channels of the vehicle network. For example, video signals may be transferred over a high-speed channel (e.g., Ethernet) while control signals may be transferred over CAN or discrete signals. The vehicle network may include any hardware and software components that aid in transferring signals and data between modules. The vehicle network is not shown in FIG. 1 but it may be implied that the vehicle network may connect to any electronic module that is present in the vehicle 112. A vehicle system controller (VSC) 148 may be present to coordinate the operation of the various components.

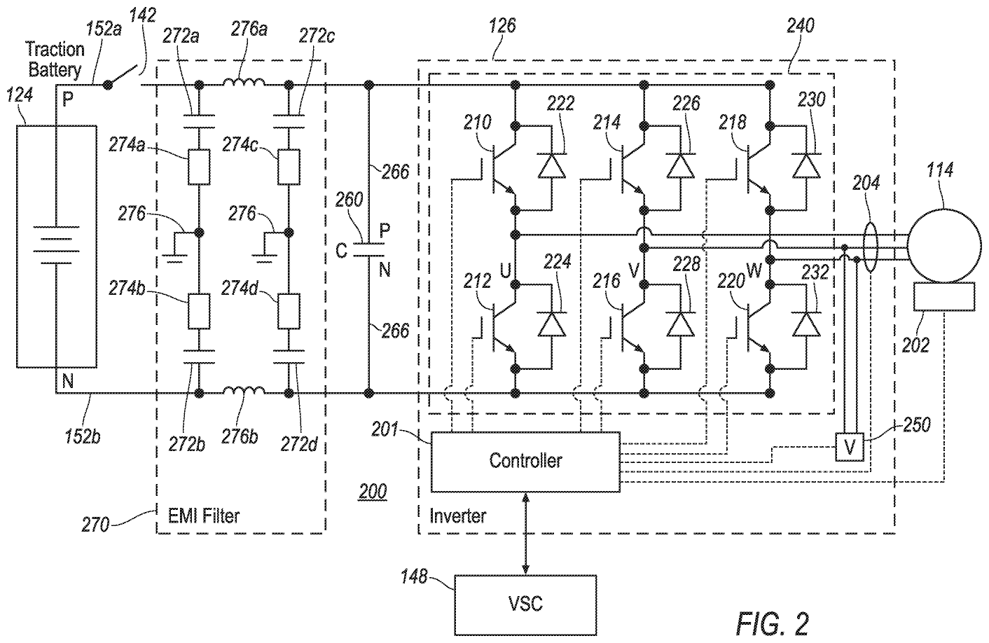

The electric machines 114 may be coupled to the power electronics module 126 via one or more conductors that are associated with each of the phase windings. Referring to FIG. 2, a diagram of a circuit 200 including a power inverter and an EMI filter for an electric machine of one embodiment of the present disclosure is illustrated. With continuing reference to FIG. 1, the vehicle 112 may include one or more power electronics controllers 201 configured to monitor and control the components of the power electronics module 126. The power electronics controllers 201 may be under a global control or coordination of the VSC 148. Further coordinated by the VSC 148 may be the main contactor 142 connected between the power electronics module 126 and the traction battery 124. As illustrated in the present example, the main contactor 142 may be connected on a positive high-voltage (HV) busbar (HV rail, DC busbar or DC rail) 152a. Under normal discharge and regenerative operating conditions, the main contactor 124 may be closed by the VSC 148 to connect the traction battery 124 to the rest of the circuit allowing the traction battery 124 to be discharged or charged.

The conductors may be part of a wiring harness between the electric machine 114 and the power electronics module 126. A three-phase electric machine 114 may have three conductors coupled to the power electronics module 126. The power electronics module 126 may be configured to switch the positive HV busbar 152a and a negative HV busbar 152b to phase terminals of the electric machines 114. The power electronics module 126 may be controlled to provide pulse-width modulated (PWM) voltage and sinusoidal current signals to the electric machine 114. The frequency and/or duty ratio of the signals may be proportional to the rotational speed of the electric machine 114. The controller 201 may be configured to adjust the voltage and current output of the power electronics module 126 at a predetermined switching frequency. The switching frequency may be the rate at which the states of switching devices within the power electronics module 126 are changed.

The power electronics module 126 may interface with a position/speed feedback device 202 that is coupled to the rotor of the electric machine 114. For example, the position/speed feedback device 202 may be a resolver or an encoder. The position/speed feedback device 202 may provide signals indicative of a position and/or speed of the rotor of the electric machine 114. The power electronics 126 may include a power electronics controller 201 that interfaces to the speed feedback device 202 and processes signals from the speed feedback device 202. The power electronics controller 201 may be programmed to utilize the speed and position feedback to control the power electronics module 126 to operate the electric machine 114.

The traction inverter or power electronics module 126 may include power switching circuitry 240 that includes a plurality of switching devices 210, 212, 214, 216, 218, 220. The switching devices 210, 212, 214, 216, 218, 220 may be Insulated Gate Bipolar Transistors (IGBT), Metal Oxide Semiconductor Field Effect Transistors (MOSFET), or other solid-state switching devices. The switching devices 210, 212, 214, 216, 218, 220 may be configured to selectively couple the positive HV busbar 152a and the negative HV busbar 152b to each phase terminal or leg (e.g., labeled U, V, W) of the electric machine 114. The power electronics module 126 may be configured to provide a U-phase voltage, a V-phase voltage, and a W-phase voltage to the electric machine 114. Each of the switching devices 210, 212, 214, 216, 218, 220 within the power switching circuitry 240 may have an associated diode 222, 224, 226, 228, 230, 232 connected in parallel to provide a path for inductive current when the switching device is in a non-conducting state. Each of the switching devices 210, 212, 214, 216, 218, 220 may have a control terminal for controlling operation of the associated switching device. The control terminals may be electrically coupled to the power electronics controller 201. The power electronics controller 201 may include associated circuitry to drive and monitor the control terminals. For example, the control terminals may be coupled to the gate input of the solid-state switching devices.

A phase leg of the inverter 126 may include switching devices and circuitry configured to selectively connect a phase terminal of the electric machine 114 to each terminal of the HV busbar 152. A first switching device 210 may selectively couple the positive HV busbar 152a to a first phase terminal (e.g., U) of the electric machine 114. A first diode 222 may be coupled in parallel to the first switching device 210. A second switching device 212 may selectively couple the negative HV busbar 152b to the first phase terminal (e.g., U) of the electric machine 114. A second diode 224 may be coupled in parallel to the second switching device 212. A first inverter phase leg may include the first switching device 210, the first diode 222, the second switching device 212, and the second diode 224.

A third switching device 214 may selectively couple the positive HV busbar 152a to a second phase terminal (e.g., V) of the electric machine 114. A third diode 226 may be coupled in parallel to the third switching device 214. A fourth switching device 216 may selectively couple the negative HV-busbar 152b to the second phase terminal (e.g., V) of the electric machine 114. A fourth diode 228 may be coupled in parallel to the fourth switching device 216. A second inverter phase leg may include the third switching device 214, the third diode 226, the fourth switching device 216, and the fourth diode 228.

A fifth switching device 218 may selectively couple the positive HV busbar 152a to a third phase terminal (e.g., W) of the electric machine 114. A fifth diode 230 may be coupled in parallel to the fifth switching device 218. A sixth switching device 220 may selectively couple the negative HV busbar 152b to the third phase terminal (e.g., W) of the electric machine 114. A sixth diode 232 may be coupled in parallel to the sixth switching device 220. A third inverter phase leg may include the fifth switching device 218, the fifth diode 230, the sixth switching device 220, and the sixth diode 232.

The power switching devices 210, 212, 214, 216, 218, 220 may include two terminals that handle the high-power current through the power switching device. For example, an IGBT includes a collector (C) terminal and an emitter (E) terminal and a MOSFET includes a drain terminal (D) and a source(S) terminal. The power switching devices 210, 212, 214, 216, 218, 220 may further include one or more control inputs. For example, the power switching devices 210, 212, 214, 216, 218, 220 may include a gate terminal (G) and a Kelvin source/emitter (K) terminal. The G and K terminals may comprise a gate loop to control the power switching device.

The power electronics module 126 may be configured to flow a rated current and have an associated power rating. Some applications may demand higher power and/or current ratings for proper operation of the electric machine 114. The power switching circuitry 240 may be designed to include power switching devices 210, 212, 214, 216, 218, 220 that can handle the desired power/current rating. The desired power/current rating may also be achieved by using power switching devices that are electrically coupled in parallel. Power switching devices may be electrically coupled in parallel and controlled with a common control signal so that each power switching device flows a portion of the total current flowing to/from the load.

The power electronics controller 201 may be programmed to operate the switching devices 210, 212, 214, 216, 218, 220 to control the voltage and current applied to the phase windings of the electric machine 114. The power electronics controller 201 may operate the switching devices 210, 212, 214, 216, 218, 220 so that each phase terminal is coupled to only one of the positive HV busbar 152a or the negative HV busbar 152b at a particular time.

Various motor control algorithms and strategies are available to be implemented in the power electronics controller 201. The power electronics module 126 may also include current sensors 204. The current sensors 204 may be inductive or Hall-effect devices configured to generate a signal indicative of the current passing through the associated circuit. In some configurations, two current sensors 204 may be utilized and the third phase current may be calculated from the two measured currents. The controller 201 may sample the current sensors 204 at a predetermined sampling rate. Measured values of the phase currents of the electric machine 114 may be stored in controller memory for later computations.

The power electronics module 126 may include one or more voltage sensors. The voltage sensors may be configured to measure an input voltage to the power electronics module 126 and/or one or more of the output voltages of the power electronics module 126. The power electronics module 126 may include a line voltage sensor 250 that is configured to measure a line voltage across the V and W phase outputs. The voltage may be a voltage difference between the V-phase voltage and the W-phase voltage. The voltage sensors may be resistive networks and include isolation elements to separate high-voltage levels from the low-voltage system. In addition, the power electronics module 126 may include associated circuitry for scaling and filtering the signals from the current sensors 204 and the voltage sensors. In some configurations, each phase leg of the inverter may have corresponding voltage and current sensors.

Under drive/discharge operating conditions, the power electronics controller 201 controls operation of the electric machine 114. For example, in response to torque and/or speed setpoints, the power electronics controller 201 may operate the switching devices 210, 212, 214, 216, 218, 220 to control the torque and speed of the electric machine 114 to achieve the setpoints. The torque and/or speed setpoints may be processed to generate a desired switching pattern for the switching devices 210, 212, 214, 216, 218, 220. The control terminals of the switching devices 210, 212, 214, 216, 218, 220 may be driven with PWM signals to control the torque and speed of the electric machine 114. The power electronics controller 201 may implement various well-known control strategies to control the electric machine 114 using the switching devices such as vector control and/or six-step control. During discharge operating conditions, the switching devices 210, 212, 214, 216, 218, 220 are actively controlled to achieve a desired current through each phase of the electric machine 114.

Under regenerative/charge operating conditions (e.g., regenerative mode), the power electronics controller 201 may control the power electronics module 126 to accommodate power generated by the electric machine 114. For example, the power electronics controller 201 may operate the switching devices 210, 212, 214, 216, 218, 220 to convert AC power generated by the electric machine 114 to DC current to charge the traction battery 124 via the HV busbar 152. The power electronics controller 201 may implement various well-known control strategies to perform the regenerative operation.

The circuit 200 may further include one or more bus capacitors 260 that are coupled across the positive HV busbar 152a and negative HV busbar 152b via a DC connection 266. As illustrated in FIG. 2, a positive terminal of the DC connection 266 connects the positive HV busbar 152a to a first terminal of the bus capacitor 260, and a negative terminal of the DC connection 266 connects the negative HV busbar 152b to a second terminal of the bus capacitor 260. Here, since the DC connection 266 is directly connected to the HV busbars 152, voltage on the DC connection 266 may be substantially the same as voltage on the HV busbars 152. The bus capacitors 260 may smooth the voltage of the DC bus 266 as well as the voltage of the HV busbars 152.

As discussed above, the power electronics module 126 may generate EMI during the drive and charge operating conditions. The EMI may affect the operations of the power electronics module 126 as well as other components of the vehicle 112 such as the traction battery 124 and the electric machine 114. The EMI noises may go out of the power electronics module 126 and affect other external systems. An EMI filter 270 may be provided to reduce and/or suppress the EMI such that the interference with components of the vehicle 112 or other external systems is minimized.

As illustrated in FIG. 2, the EMI filter 270 may include a first RC pair having a first capacitor 272a and a first resistor 274a. The first capacitor 272a includes a first terminal connected to the positive HV busbar 152a and a second terminal connected to ground 276 via the first resistor 274a. The first resistor 274a includes a first terminal connected to the second terminal of the first capacitor 272a and a second terminal connected to the ground 276. In one example the ground 276 may be implemented as one or more ground busbars 276 that are separated from the HV busbars 152.

The EMI filter 270 may include a second RC pair having a second capacitor 272b and a second resistor 274b. The second capacitor 272b includes a first terminal connected to the negative HV busbar 152b and a second terminal connected to ground 276 via the second resistor 274b. The second resistor 274b includes a first terminal connected to the second terminal of the second capacitor 272b and a second terminal connected to the ground 276.

The EMI filter 270 may include a third RC pair having a third capacitor 272c and a third resistor 274c. The third capacitor 272c includes a first terminal connected to the positive HV busbar 152a and a second terminal connected to ground 276 via the third resistor 274c. The third resistor 274c includes a first terminal connected to the second terminal of the third capacitor 272c and a second terminal connected to the ground 276.

The EMI filter 270 may include a fourth RC pair having a fourth capacitor 272d and a fourth resistor 274d. The fourth capacitor 272d includes a first terminal connected to the negative HV busbar 152b and a second terminal connected to ground 276 via the fourth resistor 274d. The fourth resistor 274d includes a first terminal connected to the second terminal of the fourth capacitor 272d and a second terminal connected to the ground 276. The first capacitor 272a, second capacitor 272b, third capacitor 272c, and fourth capacitor 272d may be referred to as Y-capacitors due to their ground connection characteristics.

The EMI filter 270 may further include a first inductor 276a connected between the first and third RC pair on the positive HV busbar 152a, and a second inductor 276b connected between the second and fourth RC pair on the negative HV busbar 152b. The first inductor 276a and second inductor 276b may form a common mode choke having the characteristics of blocking high frequency EMI noise while allowing low frequency or DC power to pass through without impedance.

The EMI filter 270 circuit may be implemented in various manners. Conventionally, the EMI filter 270 circuit is implemented via one or more printed-circuit board (PCB). The present disclosure proposes an EMI filter device and manufacture that does not require a PCB board. More specifically, the present disclosure proposes an EMI filter device that is directly placed inside an inverter system controller (ISC) housing without utilizing a PCB component.

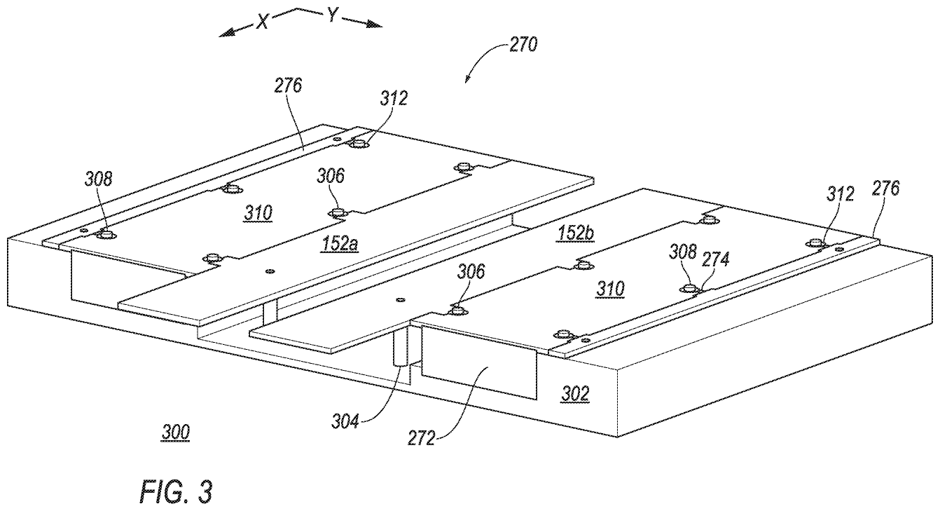

Referring to FIG. 3 a design diagram 300 of the EMI filter device 270 of one embodiment of the present disclosure. With continuing reference to FIGS. 1 and 2, the EMI filter device 270 may be placed inside an ISC housing 302 in the present implementation shown in FIG. 3. The ISC housing 302 may be made of various conductive or non-conductive materials. For instance, the ISC housing 302 may be made of aluminum alloy, magnesium alloy, or the like. Alternatively, the ISC housing 302 may be made of composite material such as fiber glass or plastic. In the present example, the positive HV busbar 152a and negative HV busbar 152b may be placed in parallel in a longitudinal direction (e.g., x axis) at a central portion of the ISC housing 302. The positive and negative HV busbars 152 may divide the ISC housing 302 into an upper bank corresponding to the positive HV busbars 152a and a lower bank corresponding to the negative HV busbar 152b. The HV busbars 152 may be attached to a bottom surface of the ISC housing 302 via one or more support pillars 304 made of insulating material such that the electric power carried by the HV busbars 152 is not transferred to the ISC housing 302. Alternatively, if the ISC housing 302 is made of non-conductive materials (e.g., fiber glass), the support pillars may be unnecessary and the HV busbars 152 may be directly coupled to an inner surface of the ISC housing 302 without requiring extra insulating elements.

The ISC housing 302 may be further configured to accommodate one or more Y-capacitors 272 that are attached to the ISC housing 302 in parallel to the HV busbars 152 in the longitudinal direction. The Y-capacitors 272 may be required to insulate from the ISC housing 302. Thus, an insulating layer may be placed in between the Y-capacitors 272 and the ISC housing 302 if the ISC housing is made of conductive materials. Alternatively, if the ISC housing is made of non-conducting materials, the insulating layer may not be required. The Y-capacitors 272 may be provided with one or more first terminals 306 configured to connect with one of the positive or negative HV busbar 152 as discussed with reference to FIG. 2. The Y-capacitors 272 may be further provided with one or more second terminals 308 configured to connect with the ground busbar 276 via one or more resistors 274. In case that the ISC housing 302 is grounded, the ground busbar 276 may be directly connected to the ISC housing 302. Alternatively, the ground busbar 276 may be insulated from ISC housing 302 and separately grounded.

The EMI filter device 270 may be further provided with an insulating cover 310 attached to a top surface of the Y-capacitors 272 and configured to provide insulation to the Y-capacitors 272. The insulating cover 310 may be made of various insulating materials such as fiber glass, plastic, or the like. The insulating cover 310 may be provided with one or more cutout portions 312 contoured accordingly and configured to accommodate the first and second terminals 306, 308 of the Y-capacitors. As illustrated in FIG. 3, the terminals 306, 308 of the Y-capacitors protrude through the top surface of the Y-capacitors for easier connection in the present disclosure. Alternatively, the terminals 306, 308 may be flush against the top surface of the Y-capacitors in which case the cutouts 312 may be unnecessary for the insulating cover 310.

The insulating cover 310 may be configured to of a size that is larger than the top surface area of the Y-capacitors such that the insulating cover 310 may overhang in the transverse direction (e.g., y-axis) toward the HV busbars 152 and/or the ground busbars 276. The top surface of the insulating cover 310 may be flush against the HV busbars 152 and/or the ground busbars 276 to form a substantially flat top surface together.

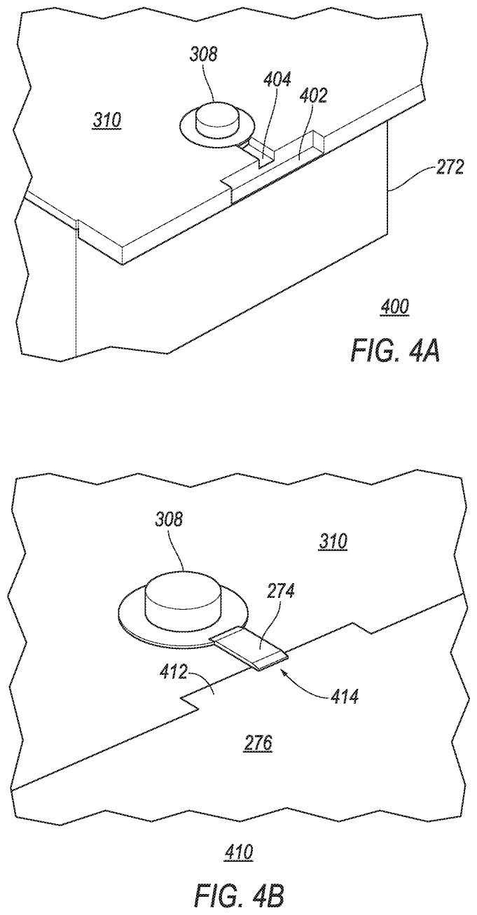

Referring to FIGS. 4A and 4B, design diagram 400 and 410 of the EMI filter device with an enlarged portion of the insulating cover are illustrated. The insulating cover 310 may be provided with a notch 402 on an edge near the second terminal 308 of the Y-capacitor 272 and configured to engage a protrusion 412 of the ground busbar 276. The notch-protrusion engagement design may increase the physical strength of the EMI filter device 270. The insulating cover 310 may be further provided with a channel 404 connecting the second terminal 308 of the Y-capacitor 272 and configured to accommodate the resistor 274. The channel 404 does not extend through the entire depth of the insulating cover 310. Instead, the channel 404 is shallower than the depth of the insulating cover 310 such that the body of the resistor 274 does not directly contact the Y-capacitor 272. In the present example, the channel 404 is approximately half the depth of the insulating cover 310. Once installed, the resister 274 is located inside the channel 404 with the first terminal connected to the second terminal 308 of the Y-capacitor 272 and a second terminal connected to the ground busbar 276. The resistor 274 may be referred to as a surface mount resistor (SMD resistor) 274 due to its mounting location. The height of the resistor 274 may be substantially the same as the depth of the channel 404 such that top surface of the resistor 274 is substantially flush with the insulating cover 310.

As illustrated in FIG. 4B, the length of the resistor 274 may be slightly longer than the length of the channel 404 which makes the second terminal protrude from the insulating cover 310 toward the ground busbar 276. To accommodate the protruding second terminal of the resistor 274, the ground busbar 276 may be further provided with a recess 414 at the corresponding location on the protrusion 412. The notch-protrusion-recess design further increases the physical strength of the EMI filter device 270. The resistor 274 may be permanently attached to both the second terminal 308 of the Y-capacitor 272 and the ground busbar 276 (e.g., via soldering). Alternatively, the resistor 274 may be removably attached to the second terminal 308 of the Y-capacitor 272 and the ground busbar 276 by friction and/or tension imposed by the channel 404, the second terminal 308, and/or the recess 414.

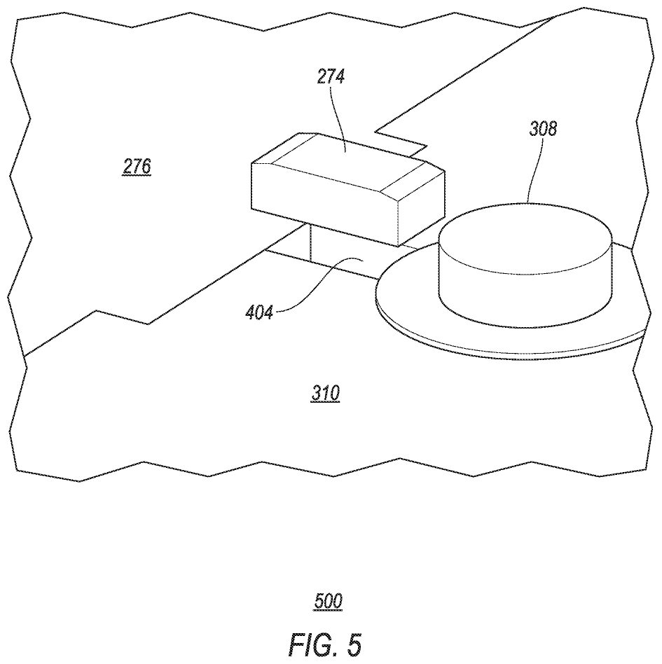

Referring to FIG. 5, a design diagram showing an enlarged portion of the EMI filter of another implementation is illustrated. Different from the example illustrated with references to FIGS. 4A and 4B, in the present example, the ground busbar 276 does not include a recess and the resistor 274 is of substantially the same length as the channel 404.

While exemplary embodiments are described above, it is not intended that these embodiments describe all possible forms encompassed by the claims. The words used in the specification are words of description rather than limitation, and it is understood that various changes may be made without departing from the spirit and scope of the disclosure.

As previously described, the features of various embodiments may be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics may be compromised to achieve desired overall system attributes, which depend on the specific application and implementation. These attributes may include, but are not limited to strength, durability, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and may be desirable for particular applications.

What is claimed is:

1. A vehicle comprising:
an electric machine for propelling the vehicle;
a battery for supplying electric power to the electric machine; and
an electromagnetic interference filter, connected between the electric machine and battery, including a housing, a capacitor disposed within and insulated from the housing, a ground busbar attached to the housing, a resistor having a first terminal connected to a terminal of the capacitor and a second terminal connected to the ground busbar, and an insulating cover at least partially covering a top surface of the capacitor.

2. The vehicle of claim 1, wherein the insulating cover defines a notch, and the ground busbar defines a protrusion configured to engage the notch.

3. The vehicle of claim 2, wherein the ground busbar further defines a recess on the protrusion configured to accommodate a portion of the resistor.

4. The vehicle of claim 1, wherein the terminal of the capacitor protrudes away from the top surface, and the insulating cover defines a cutout configured to accommodate the terminal of the capacitor.

5. The vehicle of claim 1, wherein the insulating cover defines a channel between the terminal of the capacitor and ground busbar and configured to accommodate the resistor.

6. The vehicle of claim 5, wherein a depth of the channel is less than a depth of the insulating cover.

7. The vehicle of claim 1, wherein the housing is made of conductive material, and the electromagnetic interference filter further includes an insulation layer disposed between the capacitor and housing.

8. The vehicle of claim 1, wherein the resistor is a surface mount resistor.

9. An automotive system comprising:
automotive power electronics including an electromagnetic interference filter, that lacks a printed circuit board, disposed within a housing of an inverter system controller.

10. The automotive system of claim 9, wherein the electromagnetic interference filter includes a Y-capacitor and a ground busbar each mounted to the housing, a non-conductive cap plate covering the Y-capacitor, and a surface mount resistor embedded in the non-conductive cap plate and in contact with a terminal of the capacitor and the ground busbar.

11. The automotive system of claim 10 wherein the non-conductive cap plate is plastic.

12. The automotive system of claim 10, wherein the electromagnetic interference filter further includes a DC busbar connected with the Y-capacitor.

13. The automotive system of claim 10, wherein the non-conductive cap plate defines a slot configured to accommodate the surface mount resistor.

14. An automotive component comprising:
an inverter system controller including a housing and having disposed within the housing a Y-capacitor defining a terminal, a ground busbar, and a surface mount resistor in direct contact with the terminal and ground busbar to form an electromagnetic filter that lacks a printed circuit board.

15. The automotive component of claim 14 further comprising a non-conductive cap plate covering the Y-capacitor, wherein the surface mount resistor is embedded in the non-conductive cap plate.

16. The automotive component of claim 15, wherein the non-conductive cap plate defines a slot configured to accommodate the surface mount resistor.

17. The automotive component of claim 14, wherein the Y-capacitor and ground busbar are mounted to the housing.

18. The automotive component of claim 14 further comprising a DC busbar disposed within the housing and connected with the Y-capacitor.
